(19) United States
(12) Patent Application Publication
(10) Pub. No.: US 2014/0356768 A1
(43) Pub. Date: Dec. 4, 2014

(54) CHARGED BEAM PLASMA APPARATUS FOR PHOTOMASK MANUFACTURE APPLICATIONS

(71) Applicants: Banqiu WU, San Jose, CA (US); Ajay KUMAR, Cupertino, CA (US); Amitabh SABHARWAL, San Jose, CA (US); Leonid DORF, San Jose, CA (US); Ming-Feng WU, San Jose, CA (US); Shahid RAUF, Pleasanton, CA (US); Kartik RAMASWAMY, San Jose, CA (US); Kenneth S. COLLINS, San Jose, CA (US); Omkaram NALAMASU, San Jose, CA (US)

(72) Inventors: Banqiu WU, San Jose, CA (US); Ajay KUMAR, Cupertino, CA (US); Amitabh SABHARWAL, San Jose, CA (US); Leonid DORF, San Jose, CA (US); Ming-Feng WU, San Jose, CA (US); Shahid RAUF, Pleasanton, CA (US); Kartik RAMASWAMY, San Jose, CA (US); Kenneth S. COLLINS, San Jose, CA (US); Omkaram NALAMASU, San Jose, CA (US)

(21) Appl. No.: 13/904,716

(22) Filed: May 29, 2013

(51) Int. Cl. G03F 1/80

(52) U.S. Cl. CPC G03F 1/80
USPC 430/5; 422/186.29

(57) ABSTRACT

Embodiments of the present invention generally provide an apparatus and methods for etching photomasks using charged beam plasma. In one embodiment, an apparatus for performing a charged beam plasma process on a photomask includes a processing chamber having a chamber bottom, a chamber ceiling and chamber sidewalls defining an interior volume, a substrate support pedestal disposed in the interior volume, a charged beam generation system disposed adjacent to the chamber sidewall, and a RF bias electrode disposed in the substrate support.

### BACKGROUND

1. Field

Embodiments of the present invention generally relate to an apparatus and methods for fabricating a photomask substrate and, more specifically, to an apparatus and methods for fabricating a photomask substrate utilizing a charged beam plasma apparatus for semiconductor processes.

2. Description of the Related Art

In the manufacture of integrated circuits (IC), or chips, patterns representing different layers of the chip are created by a chip designer. A series of reusable masks, or photomasks, are created from these patterns in order to transfer the design of each chip layer onto a semiconductor substrate during the manufacturing process. Mask pattern generation systems use precision lasers or electron beams to image the design of each layer of the chip onto a respective mask. The masks are then used much like photographic negatives to transfer the circuit patterns for each layer onto a semiconductor substrate. These layers are built up using a sequence of processes and translate into the tiny transistors and electrical circuits that comprise each completed chip. Thus, any defects in the mask may be transferred to the chip, potentially adversely affecting performance. Defects that are severe enough may render the mask completely useless. Typically, a set of 15 to 30 masks is used to construct a chip and can be used repeatedly.

The next generation photomask as further discussed below is formed on a low thermal expansion glass or a quartz substrate having a multilayer film stack disposed thereon. The multilayer film stack may include at least an absorber layer and a photomask shift mask layer. When manufacturing the photomask, a photoresist layer is disposed on the film stack to facilitate transferring features into the film stack during the subsequent patterning processes. During the patterning process, the circuit design is written onto the photomask by exposing portions of the photoresist to electron beam or deep ultraviolet light, making the exposed portions soluble in a developing solution. The soluble portion of the resist is then removed, allowing the underlying film stack exposed through the remaining photoresist to be etched. The etch process removes the film stack from the photomask at locations where the resist was removed, i.e., the exposed film stack is removed.

In order to increase the pattern resolution, a thinner photoresist layer is often desired to avoid undesired light scattering during the lithography process. During an etching process, the photoresist layer may be consumed or deformed. Insufficient thickness of the photoresist layer may cause early consumption or exhaustion of the photoresist layer on the substrate, thereby resulting in feature transfer failure to the substrate. However, overly thick photoresist layer formed on the substrate may affect the pattern resolution, resulting in poor line integrity of the formed features on the substrate. Therefore, controlling the photoresist layer thickness at a minimum range increases challenge for control of the photomask etching process in defect control and pattern fidelity.

Therefore, there is an ongoing need for an improved etching process in photomask fabrication that may be able to use thin photoresist layers while maintaining good profile control for the features transferred onto the photomask substrate.

### SUMMARY

Embodiments of the present invention generally provide an apparatus and methods for etching photomasks using charged beam plasma. Embodiments of the present invention also generally relate to photomask manufacture technology for binary, PSM, OMOG and EUV Lithography using a charged beam plasma process. In one embodiment, an apparatus for performing a charged beam plasma process on a photomask includes a processing chamber having a chamber bottom, a chamber ceiling and chamber sidewalls defining an interior volume, a substrate support pedestal disposed in the interior volume, a charged beam generation system disposed adjacent to the chamber sidewall, and a RF bias electrode disposed in the substrate support.

In another embodiment, a method for forming a charged beam plasma for manufacturing a photomask layer includes transfering a photomask having a material layer disposed on the photomask into a processing chamber, generating a charged beam plasma in the processing chamber above the photomask, ionizing an etching gas mixture supplied into the processing chamber by the charged beam plasma, and etching the material layer disposed on the photomask with the ionized etching gas mixture.

In yet another embodiment, a method for forming an electron beam plasma for manufacturing a photomask layer includes providing a photomask having a material layer disposed on the photomask into a processing chamber, applying a DC power to an electron beam generation system disposed to the processing chamber to form a electron beam plasma, accelerating the electron beam plasma to laterally distribution the electron beam plasma across and above the photomask at a predetermined distance, ionizing an etching gas mixture supplied into the processing chamber by the electron beam plasma, and etching the material layer disposed on the photomask in the presence of the ionized etching gas mixture.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic cross-sectional view of a charged beam plasma processing chamber that may be utilized to fabricate a photomask in accordance with one embodiment of the present invention;

FIG. 2 depicts a method for fabricating a photomask using the charged beam plasma processing chamber depicted in FIG. 1 in accordance with one embodiment of the present invention;

FIG. 3A-3D depict one embodiment of a material layer suitable for manufacturing a photomask at different stages of the method depicted in FIG. 2 in accordance with one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides a method and apparatus for etching a photomask substrate using a charged beam plasma processing chamber. In one embodiment, an electron beam plasma processing chamber may be utilized to etch a material layer disposed on a quartz substrate to form a photomask for semiconductor device manufacture. It is noted that ion beam plasma process chamber may also utilized to perform for photomask manufacture process described herein. The electron beam plasma processing chamber utilizes an electron beam generation system to generate electron beam plasma, providing mild etching species during processing, thereby gently etching the material layer on the substrate with minimum damage to the photoresist layer disposed thereon. Although the discussion and illustrative examples focus on reducing photoresist thickness loss and utilizing of electron beam plasma during an etching process, various embodiments of the invention can also be adapted for process of etching other suitable substrates, including transparent substrates, optical disks, dielectric substrates or other semiconductor wafers.

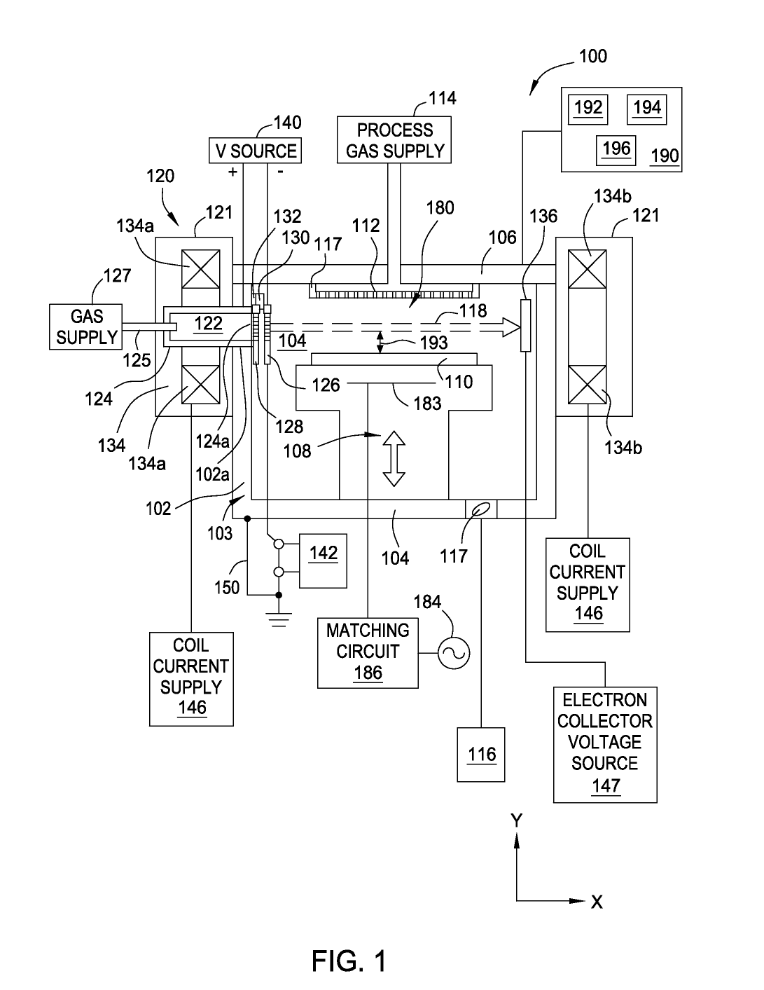

FIG. 1 is a schematic cross sectional view of a charged beam plasma processing chamber 100 in accordance with one embodiment of the invention. Although the particular embodiment of the charged beam plasma processing chamber 100 shown herein is an electron beam plasma processing chamber, it is noted that other types of the charged beam plasma processing chamber, such as ion beam plasma processing chamber may also be utilized as needed. The particular embodiment of the charged beam plasma processing chamber 100 provided herein is only for illustrative purposes and should not be used to limit the scope of the invention. It is contemplated that the invention may be utilized in other processing systems, including those from other manufacturers.

The processing chamber 100 generally includes a cylindrical sidewall 102, a ceiling 106 mounted on the cylindrical sidewall 102, and a chamber bottom 104 defining an internal volume 180 inside a chamber body 103. The ceiling 106 may be flat, rectangular, arcuate, conical, dome or multi-radius shaped. The chamber body 103 may be fabricated from a metal, such as anodized aluminum, and the ceiling 106 can be made of an energy transparent material such as a ceramic or other dielectric material.

A gas distribution plate 112 is integrated with or mounted on the ceiling 106, and receives process gas from a process gas supply 114. The process gas supply 114 provides a gas mixture that is introduced into the internal volume 180 through the gas distribution plate 112 to process a substrate 110, such as a photomask substrate, disposed on a substrate support pedestal 108. In one embodiment, processing gases that may be used to supply from the process gas supply 114 to the processing chamber include a fluorinated and carbon gas, halogen containing gas, chlorine containing gas, a carbon containing gas, an oxygen gas and a nitrogen containing gas. Examples of fluorinated and carbon containing gases include CH₄, CHF₃ and CF₄. Other fluorinated gases may include one or more of CF₄, C₂F₆, C₂F, C₄F₆, C₃F₈ and C₅F₈. Halogen containing gas include HBr, HCl and Cl₂. Examples of the oxygen containing gas include O₂, CO₂, CO, N₂O, NO₂, O₃, H₂O, and the like. Examples of the carbon containing gas include CO₂, CO, CH₄, C₂H₆, C₂H₄ and the like. Examples of the nitrogen containing gas include N₂, NH₃, N₂O, NO₂ and the like. Examples of the chlorine containing gas include HCl, Cl₂, CCl₄, CHCl₃, CH₂Cl₂, CH₃Cl, and the like.

The substrate support pedestal 108 is disposed in the processing chamber 100 above the bottom 104 of the chamber body 103 to support the substrate 110 during processing. The substrate support pedestal 108 may be movable in the axial (e.g., vertical) direction. In one embodiment, the substrate support pedestal 108 is configured as a cathode and includes an electrode 183 that is coupled to a RF bias power source 184. The RF bias power source 184 is coupled between the electrode 183 disposed in the substrate support pedestal 108 and another electrode, such as the gas distribution plate 112 or ceiling 106 of the chamber body 103. The RF bias power provided by the source 184 excites and sustains a plasma discharge formed from the gases disposed in the processing region 104 of the chamber body 103.

In the embodiment depicted in FIG. 1, the RF bias power source 184 is coupled to the electrode 183 disposed in the substrate support pedestal 108 through a matching circuit 186. The signal generated by the RF bias power source 184 is delivered through matching circuit 186 to the substrate support pedestal 108 through a single feed to accelerate ionized gas mixture toward the substrate support pedestal 108. The RF bias power source 184 is generally capable of producing an RF signal having a frequency of from about 50 kHz to about 200 MHz and a power between about 0 Watts and about 5000 Watts.

A vacuum pump 116 evacuates the internal volume 180 of the chamber 100 through an outlet port 117 formed in the bottom 104 of the chamber body 103. The processing region 104 is defined inside the internal volume 180 between the substrate support pedestal 108 and the gas distribution plate 112. Within the processing region 104, the process gas is ionized to produce a plasma for processing of the substrate 110.

An electron beam generation system 120 is disposed around an outer region of the chamber body 103 around the chamber sidewall 102. The electron beam generation system 120 includes an electron beam generation source 122 disposed outside of and adjacent to the processing chamber 100. A conductive housing 124 is disposed around and covers the electron beam generation source 122 from the ambient environment outside for the chamber 100. An electron beam source gas supply 127 is connected to the electron beam generation source 122 through a gas inlet 125. The electron beam source gas supply 127 is configured to supply gases to the electron beam generation source 122 to generate an electron beam plasma during processing. The conductive housing 124 includes an opening 124a facing the processing region 104 through an opening 102a formed in the sidewall 102 of the processing chamber 100.

The electron beam generation system 120 includes a profiled extraction grid 126 disposed between the processing region 104 and the electron beam generation source 122. An acceleration grid 128 is disposed between the extraction grid 126 and the electron beam generation source 122. The profiled extraction grid 126 and the acceleration grid 128 may be formed as separate conductive sheets having apertures or holes formed therethrough, or as meshes, for example. The extraction grid 126 and the acceleration grid 128 are mounted with insulators 130, 132, respectively, so as to be electrically insulated from one another and from the conductive housing 124.

In one embodiment, the acceleration grid 128 is in electrical contact with the sidewall 102 of the chamber 100. The openings 124a and 102a and the extraction and acceleration grids 126, 128 are mutually congruent, generally, and define a thin wide electron beam flow path 118 (i.e., thin in the y direction while wide in the z direction) for an electron beam to laterally flow into the processing region 104. The electron beam flow path 118 may have a width in the z direction about the same as a diameter of the substrate 110 (e.g., 100-500 mm), while the height of the flow path in the y direction may be less than about two inches.

The electron beam generation system 120 further includes a pair of electromagnets 134a, 134b aligned with the electron beam generation source 122, and producing a magnetic field parallel to the direction of the electron beam as generated (for example, in the x direction). The electromagnets 134a, 134b confine the electron beam, enhancing its plasma electron density. The electron beam flows laterally in the x direction across the processing region 104, as indicted by the flow path 118, space above the substrate 110 by a predetermined distance 193. In one embodiment, the predetermined distance 193 may be maintained at between about 2 mm and about 50 mm during processing. The electron beam passing above the substrate 110 is then absorbed and collected on the opposite side of the processing region 104 relative to the electron beam generation source 122 by an electron beam collector 136. The electron beam collector 136 is a conductive body having a shape and size adapted to capture the wide thin path of the electron beam along the path 118. The electron beam collector 136 may be held at a selected electrical potential, such as ground. An electron collector voltage source 147 is coupled to the electron beam collector 136 configured to supply a voltage to the electron beam collector 136 when drawing electrons from the electron beam generation source 122.

Referring back to the electron beam generation source side of the chamber 100, a negative terminal of a plasma DC discharge voltage supply 140 is coupled to the conductive housing 124, while a positive terminal of the voltage supply 140 is coupled to the extraction grid 126. In turn, a negative terminal of an electron beam acceleration voltage supply 142 is connected to the extraction grid 126, and a positive terminal of the voltage supply 142 is connected to the grounded chamber body 103 of the processing chamber 100.

A coil current supply 146 is coupled to the electromagnets 134a and 134b. Electron beam is generated within the electron beam generation source 122 of the electron beam generation system 120 by a DC gas discharge produced by power from the voltage supply 140, to produce an electron beam plasma within the electron beam generation source 122. This DC gas discharge is the main source of electrons in the electron beam generation system 120. Electrons are extracted from the electron beam generation source 122 through the extraction grid 126 and the acceleration grid 128 to produce an electron beam that flows into the processing chamber 100. Electrons are accelerated to energies equal to the voltage provided by the beam acceleration voltage supply 142.

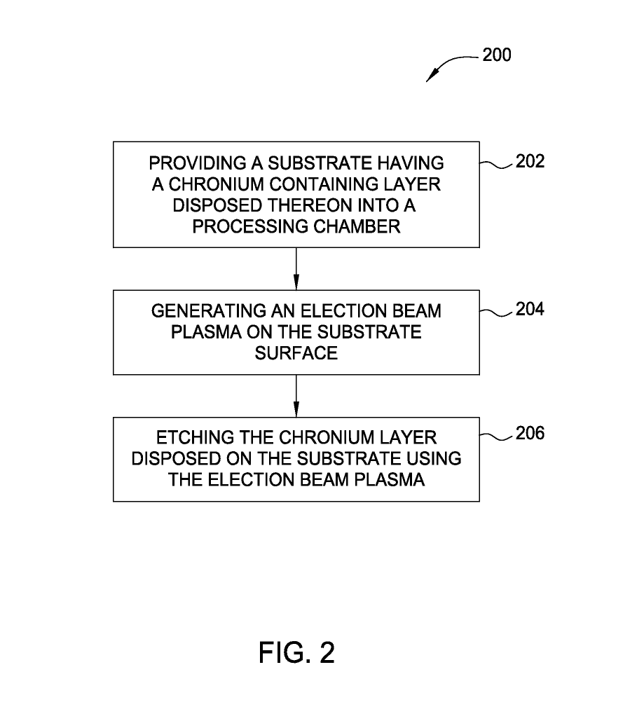

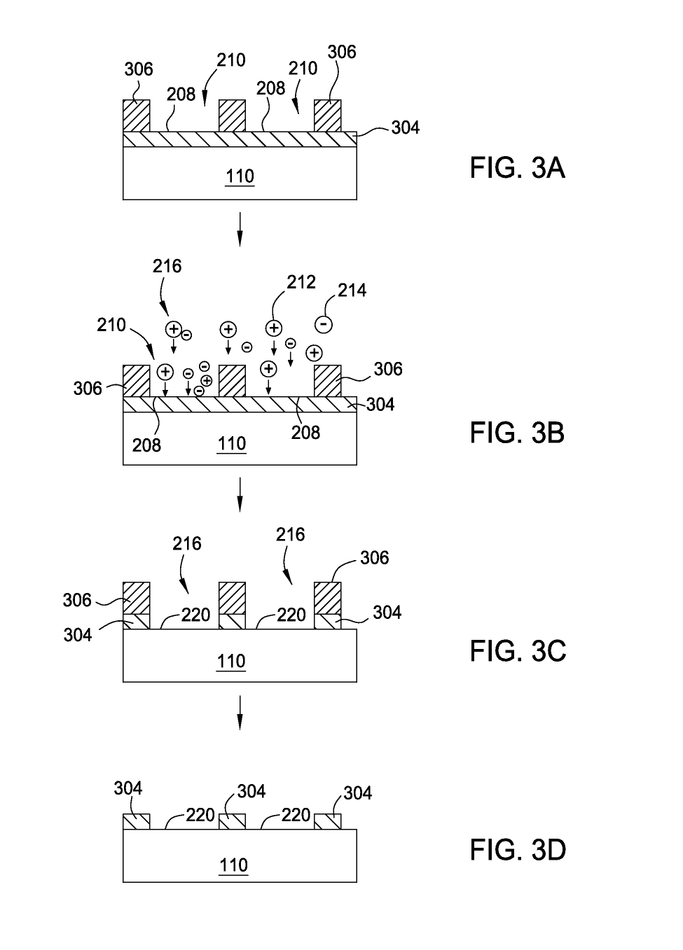

The electron beam generated from the electron beam generation source 122 ionizes the processing gases supplied from the process gas supply 114 into the processing region 104, forming electron beam plasma in the processing region 104. The electron beam plasma includes ions with different charges. The charged ions may be accelerated toward the substrate 110 as a result from a bias power from the RF bias power source 184. The charged ions may then react with the material layers disposed on the substrate 110, thereby etching and removing the material layer exposed by a patterned photoresist layer on the substrate 110. Details regarding how the electron beam plasma process is performed will be further discussed below with referenced to FIGS. 2-3D.

A controller 190 is coupled to the processing chamber 100 to control operation of the processing chamber 100. The controller 190 includes a central processing unit (CPU) 192, a memory 194, and a support circuit 196 utilized to control the process sequence and operate processes in the processing chamber 100. The CPU 192 may be any form of general purpose computer processor that may be used in an industrial setting. The software routines can be stored in the memory 194, such as random access memory, read only memory, floppy, or hard disk drive, or other form of digital storage. The support circuit 196 is conventionally coupled to the CPU 192 and may include cache, clock circuits, input/output systems, power supplies, and the like. Bi-directional communications between the controller 190 and the various components of the processing system 100 are handled through numerous signal cables.

FIG. 2 is a flow diagram of one embodiment of a method 200 for etching a material layer, such as an absorber layer, having a patterned photoresist layer disposed on a photomask substrate, such as a material layer 304 having a patterned photoresist layer 306 disposed on a photomask substrate 110 depicted in FIG. 3A. The photomask substrate 110 that may be utilized to form desired features (i.e., openings 210) in the material layer 304. Although the method 200 is described below with reference to a substrate utilized to fabricate a photomask, the method 200 may also be used to advantage in other photomask etching or any etching application.

The method 200 begins at block 202 when the photomask substrate 110 is transferred to and placed on a substrate support pedestal disposed in an processing chamber, such as the electron beam plasma processing chamber 100 depicted in FIG. 1. As described above, the photomask substrate 110 includes an optically transparent silicon based material, such as quartz or low thermal expansion glass layer having the material layer 304 disposed thereon defined by the patterned photoresist layer 306 having portions 208 of the material layer 304 exposed through the patterned photoresist layer 306. In one embodiment, a phase shift mask layer (not shown) may be optionally disposed between the substrate 110 and the material layer 304.

In one embodiment, the substrate 110 has a rectangular shape having sides between about 5 inches to about 9 inches in length. The photomask substrate 110 may be between about 0.15 inches and about 0.25 inches thick. In one embodiment, the substrate 110 is about 0.25 inches thick. The material layer 304, e.g., the absorber layer, may be a metal containing layer, e.g., a chromium containing layer, such as a Cr metal, chromium oxide (CrOₓ), chromium nitride (CrN) layer, chromium oxynitride (CrON), or multilayer comprised of one or more of these materials, as needed. The optional phase shift mask layer may be a molybdenum containing layer, such as Mo layer, MoSi layer, MoSiN, MoSiON, and the like. The patterned photoresist layer 306 is then formed over the material layer 304 having openings 210 formed therein that expose portions 208 of the material layer 304 for etching. The photoresist layer 306 may comprise any suitable photosensitive resist materials, such as an e-beam resist (for example, a chemically amplified resist (CAR)), and deposited and patterned in any suitable manner. The photoresist layer 306 may be deposited to a thickness between about 50 nm and about 1000 nm.

At block 204, a charged beam plasma process is performed to generate a charged beam plasma laterally across the surface of the substrate 110, as shown in FIG. 3B. The charged beam plasma process may be an electron beam plasma process or an ion beam plasma process. In the particular embodiment depicted herein, the charged beam plasma process is an electron beam plasma process. The electron beam plasma generated from the electron beam generation system 120 etches the material layer 304 disposed on the substrate 110. The patterned photoresist layer 306 may serve as a mask layer to protect some portion of the material layer 304 from being etched during the material layer etching process. The electron beam plasma process etches the material layer 304 through the openings 210 defined by the patterned photoresist layer 306 until the material layer 304 is removed, exposing an underlying surface 220 of the substrate 110, as shown in FIG. 3C.

During the electron beam plasma process, an etching gas mixture may be supplied from either the process gas supply 114 or from the gas supply 127. In one embodiment, the etching gas mixture is dominantly supplied from the process gas supply 114, while an inert gas, such as He or Ar, is dominantly supplied from gas supply 127 to assist carrying the electron beam generated from the electron beam generation system 120 into the processing region 104. In one embodiment, the etching gas mixture supplied to the processing chamber 100 includes at least a halogen-containing gas. The halogen containing gas may be at least one of a fluorine containing gas, chlorine containing gas, and bromide containing gas. Suitable examples of the fluorine containing gas include CHF₃, CF₄, C₂F, C₄F₆, C₃F₈ and C₅F₈ and the like. Suitable examples of the fluorine containing gas include bromide containing gas include HBr, Br₂ and the like. Suitable examples of the chlorine containing gas include HCl, Cl₂, CCl₄, CHCl₃, CH₂Cl₂, CH₃Cl. In one embodiment, an oxygen containing gas may also be supplied in the etching gas mixture. Suitable examples of the oxygen containing gas includes O₂, CO₂, CO, N₂O, NO₂, O₃, H₂O, and the like.

In one embodiment, the etching gas mixture supplied during the electron beam plasma process includes a chlorine containing gas and an oxygen containing gas. In one example, the chlorine containing gas supplied in the etching gas mixture is Cl₂ and the oxygen containing gas supplied in the etching gas mixture is O₂ or CO₂.

As discussed above, during processing, the electron beam plasma as generated ionizes the gases supplied in the etching gas mixture, forming charged ions 212, 214 on the substrate surface, as shown in FIG. 3B. The ions may be positive ions 212 or negative ions 214. The charged ions 212, 214, may gently react with the material layer 304 exposed by the patterned photoresist layer 306. As the gases supplied into the processing chamber 100 is ionized by the electron beam laterally passing through and above the substrate surface, a relatively mild etching process may be obtained, as the energy from the electron beam does not directly contact or travel to the substrate surface. In conventional inductive coupled plasma (ICP) chamber configuration, a voltage selected to ignite an RF power in an ICP chamber must meet certain threshold voltage so as to enable and create a plasma in the ICP processing chamber. However, such aggressive RF power often results in substrate damage, chamber arcing, chamber component damage or excess photoresist consumption during the etching process, thereby resulting in inaccurate feature transfer after the etching process. Therefore, by utilizing this mild electron beam plasma process, the electron beam as generated is maintained at a distance away from the substrate surface, while ionizing the gases into charged ions 212, 214 above the substrate 110. The charged ions 212, 214 are then accelerated and drawn to the substrate surface, as a result of the RF bias power supplied to the substrate support pedestal 108. The accelerated charged ions 212, 214 then react with the material layer 304 exposed by the photoresist layer 306, removing the material layer 304 from the substrate 110. By doing so, use of the conventional aggressive plasma source power may be eliminated from the etching chamber. Instead, the electron beam plasma process provides a mild ionization process that is used to form ions with lower striking energy to gently react with the material layer 304 without overly attacking the photoresist layer 306, compared o the conventional ICP processes. In this manner, the likelihood of the photoresist layer 306 being early consumed during the etching process can be significantly reduced, thus sustaining the photoresist layer 306 on the substrate 110 until completion of the etching process. In some embodiment, a thin photoresist layer 306, such as less than 50 nm, may be utilized as the consumption of the photoresist layer during the etching process is minimized by utilizing the electron beam plasma process.

At block 206, after the electron beam plasma is generated in the processing chamber 100, the material layer 304 is then etched from the substrate 110, exposing the underlying surface 220 of the substrate 110, as shown in FIG. 3C. In one embodiment, the chlorine containing gas and the oxygen containing gas supplied in the etching gas mixture is Cl₂ and O₂. The inert gas supplied in the etching gas mixture is Ar or He. In one particular embodiment, the Cl₂ gas and the O₂ gas may be supplied in the etching gas mixture at a ratio between about 15:1 and about 2:1. The O₂ gas flowed into the chamber at a rate between about 10 sccm to about 100 sccm. The Cl₂ may be supplied at a rate between about 20 sccm and about 200 sccm. The inert gas, such as Ar or He, may be supplied in the gas mixture between about 50 sccm and about 300 sccm. Also, the gas mixture supplied from the the gas supply 127 is maintained at between about 20 sccm and about 300 sccm.

Several process parameters are regulated while the etching mixture at block 206 supplied into the processing chamber. In one embodiment, the chamber pressure in the presence of the etching gas mixture is regulated between about 1 mTorr to about 40 mTorr. A substrate temperature may be maintained between about 10 degrees Celsius to about 500 degrees Celsius, such as about 15 degrees Celsius.

A voltage from between about 300 volts and about 600 volts may be supplied to the plasma DC discharge voltage supply 140. A voltage from between about 400 volts and about 3000 volts may be supplied to the electron beam acceleration voltage supply 142. A low range of RF bias power may be applied to assist drive ions ionized from the etching gas mixture toward the substrate surface. For example, a RF bias power of less than 150 watts, such as between about 10 watts to about 50 watts, may be applied to maintain gentle and mild electron beam plasma inside the etch chamber without aggressively attacking the substrate. The RF bias power may have a frequency between about 1 MHz and about 20 MHz.

After the material layer 304 is removed from the substrate 110, the remaining photoresist layer, if any, is then removed by ashing, as shown in FIG. 3D. The removal process may be performed in-situ the processing chamber 100 in which the electron beam plasma process is performed. In the embodiment wherein the photoresist layer 306 is completely consumed during the etching process, the ashing or photoresist layer removal process may be eliminated.

Thus, methods and apparatus for performing a charged beam plasma process are provided. The charged beam plasma process utilizes an electron beam generation system disposed in a processing chamber to provide electron beam laterally crossing a substrate surface at a predetermined distance above the substrate surface. The electron beam plasma ionizes the gas mixture to provide mild ions to etch the material layer disposed on the substrate without overly attack the photoresist layer, thereby efficiently maintaining good profile of the resultant features transferred to the material layer. Furthermore, a thinner photoresist layer may be used to provide good lithography resolution while maintaining desired feature profile transfer.

While the foregoing is directed to embodiments of the present invention, other and further embodiments of the invention may be devised without departing from the basic scope thereof, and the scope thereof is determined by the claims that follow.

1. An apparatus for performing a charged beam plasma process on a photomask, comprising:
a processing chamber having a chamber bottom, a chamber ceiling and chamber sidewalls defining an interior volume;
a substrate support pedestal disposed in the interior volume;
a charged beam generation system disposed adjacent to the chamber sidewall; and
a RF bias electrode disposed in the substrate support.

2. The apparatus of claim 1, wherein the charged beam generation system is an electron beam generation system.

3. The apparatus of claim 2, wherein the electron beam generation system further comprises:
an electron beam generation source disposed in a conductive housing coupled to the sidewall of the processing chamber;
an extraction grid disposed between the electron beam generation source and the substrate support pedestal; and
an electron beam collector disposed on a side of the substrate support pedestal opposite to the extraction grid.

4. The apparatus of claim 3, further comprising:
an acceleration grid disposed between the extraction grid and the substrate support pedestal.

5. The apparatus of claim 3, wherein a DC power supply is coupled to the electron beam generation source.

6. The apparatus of claim 4, further comprising:
an electron beam acceleration voltage supply coupled to the acceleration grid.

7. The apparatus of claim 1, further comprising:
a process gas supply coupled to the ceiling of the processing chamber.

8. The apparatus of claim 3, further comprising:
an electron collector voltage source coupled to the electron beam collector.

9. The apparatus of claim 3, further comprising:
a gas supply coupled to the electron beam generation source.

10. The apparatus of claim 1, wherein the substrate support pedestal is configured to retain a photomask.

11. The apparatus of claim 1, wherein the charged beam is an ion beam.

12. A method for forming a charged beam plasma for manufacturing a photomask layer, comprising:
transfering a photomask having a material layer disposed on the photomask into a processing chamber;
generating a charged beam plasma in the processing chamber above the photomask;
ionizing an etching gas mixture supplied into the processing chamber by the charged beam plasma; and
etching the material layer disposed on the photomask with the ionized etching gas mixture.

13. The method of claim 12, wherein the charged beam plasma is an electron beam plasma.

14. The method of claim 12, wherein generating the charged beam plasma further comprises:
laterally forming an electron beam plasma above the photomask at a distance of between about 2 mm and about 50 mm.

15. The method of claim 12, wherein the etching gas mixture includes at least a chlorine containing gas and a oxygen containing gas.

16. The method of claim 12, wherein the material layer is a chromium containing layer.

17. The method of claim 12, further comprising:
applying a bias power to the photomask while etching the material layer.

18. The method of claim 12, wherein the charged beam plasma is an ion beam plasma.

19. A method for forming an electron beam plasma for manufacturing a photomask layer, comprising:
providing a photomask having a material layer disposed on the photomask into a processing chamber;
applying a DC power to an electron beam generation system disposed to the processing chamber to form a electron beam plasma;
accelerating the electron beam plasma to laterally distribution the electron beam plasma across and above the photomask at a predetermined distance;
ionizing an etching gas mixture supplied into the processing chamber by the electron beam plasma; and
etching the material layer disposed on the photomask in the presence of the ionized etching gas mixture.

20. The method of claim 19, further comprising:
applying a bias power to the photomask while etching the material layer.
